(19) United States
(12) Patent Application Publication
(10) Pub. No.: US 2004/0233767 A1
(43) Pub. Date: Nov. 25, 2004

(54) Method and system of fault patterns oriented defect diagnosis for memories

(76) Inventors: Cheng-Wen Wu, Hsinchu (TW); Chih-Tsun Huang, Chiayi (TW); Chih-Wea Wang, Jhonghe (TW); Kuo-Liang Cheng, Sinying (TW); Jih-Nung Lee, Taipei (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/819,136

(22) Filed: Apr. 7, 2004

(30) Foreign Application Priority Data
May 21, 2003 (TW) 092113766

(51) Int. Cl. G11C 7/00

(52) U.S. Cl. 365/232

(57) ABSTRACT

A method and system of fault patterns oriented defect diagnosis for memories can analyze and recognize fault patterns and failure patterns after Memory Error Catches and Analyses (MECA) are done. The existent fault patterns are compared with a pre-simulated and grouped defect dictionary that defines possible defects of different fault patterns, and the defects of memories caused from their manufacturing process or circuit layout can be detected.

### BACKGROUND OF THE INVENTION

1. Field of the Invention

The present invention relates to a method and system of defect diagnosis for memories, and more particularly to a method and system of memory defect diagnosis oriented by fault patterns.

2. Description of the Related Art

Memories are basic components applied to general digital systems, and occupy most of a system-on-chip (SoC) area on an embedded design; hence they can usually determine whether or not the yield of the SoC devices is high. Since the capacity and density of the embedded memories are dramatically increased, memory tests become more difficult and complicated. In order to improve the yield of the SoC devices, the memory diagnosis and failure analysis (FA) become critical issues.

Because defects occurring in the manufacturing process of a wafer usually result in a low yield, the FA can detect the root causes of the low yield. According to the result of the FA, IC design engineers can decide how to improve the manufacturing process and modify the corresponding circuit design, so as to improve the yield.

The rule of the conventional FA is to detect and indicate defective memory cells or regions where exist, and then to conduct a series of reverse engineering operations. Afterwards, an electron beam probe or an electron microscope can find and confirm the root causes of these defects. However, the conventional FA is not applicable to defect-level tests or memory diagnoses due to the lack of adequate methods and tools when the process technology enters the deep sub-micro era.

Bitmaps and wafer maps are commonly used during the FA because the occurrence and locations of failure patterns are helpful for the engineers to screen out the potential causes of failures. Experienced engineers are perhaps qualified to properly diagnose the root causes. Yet, it is difficult for most inexperienced engineers or even some experienced engineers to find the root causes to improve the yield.

On the other hand, various new fault models and test algorithms are continuously developed in order to cover the probable defects and failure causes existing in memories. The fault models are designed to classify functional failures, and test algorithms are used to detect whether or not problems designated by fault models exist. Generally speaking, the performance of a test algorithm is determined by its testing length and fault coverage.

Nevertheless, both failure patterns and failure bitmaps have many disadvantages; for example, various root causes are referred to the same failure pattern so as to have an inaccurate diagnostic result. On the other hand, fault models are not enough for test algorithms to detect all possible defects although new fault models are continuously developed. However, the root causes of the failures referred to one of the fault models can be recognized by certain manual analyses lately.

In conclusion, a method for the automatic FA and defect diagnosis is very necessary for current testing markets to solve the problems occurring in the aforementioned memory test and the improvement of the yield.

### SUMMARY OF THE INVENTION

The first objective of the present invention is to provide an automatic method and system of defect diagnosis for memories which utilize fault patterns incorporated with bitmaps and fault models, thus the FA is more capable of discriminating defects and reducing the time of engineer's confirmation by their experiences.

The second objective of the invention is to provide a method and system of defect diagnosis for improving the yield of memories. Circuit designers and product engineers can easily discriminate the real root causes of memory failures by means of this method, so they can effectively improve the yield.

In order to achieve these objectives, the present invention discloses a method and system of fault patterns oriented defect diagnosis for memories that can analyze and recognize fault patterns and failure patterns after Memory Error Catches and Analyses (MECA) are done. The existent fault patterns are compared with a pre-simulated and grouped defect dictionary that defines possible defects of different fault patterns, and the defects of memories caused from their manufacturing process or circuit layout can be detected. This method also employs a graphic user interface (GUI) to display and designate memory cells where defects exist as fault models and fault patterns, thus the circuit designers and product engineers can easily discriminate the real root causes of memory failures.

### BRIEF DESCRIPTION OF THE DRAWINGS

The invention will be described according to the appended drawings in which:

FIG. 1 is a schematic diagram of a failure bitmap;

FIG. 2 is a schematic diagram of a fault bitmap;

FIGS. 3(a)-3(d) are schematic diagrams of four types of failure patterns;

FIGS. 4(a)-4(f) are schematic diagrams of fault patterns displaying a memory array consisting of 5×5 memory cells in accordance with the present invention;

FIG. 5 is a framework and flow diagram of a defect diagnosis system for memories in accordance with the present invention; and

FIG. 6 is a schematic diagram of a GUI page for browsing a diagnostic result in accordance with the present invention.

### PREFERRED EMBODIMENT OF THE PRESENT INVENTION

Generally speaking, adequate fault models are selected as error detectable orientations before a test algorithm is executed. The fault models for memory tests usually include SAF (stuck-at fault), TF (transition fault), SOF (stuck-open fault), AF (address decoder fault), CF (coupling fault) and RDF (read disturb fault). Defects of memories can be detected through the fault models, and the root causes of the defects are to be analyzed further.

Among numerous test algorithms, the one based on a March algorithm can more easily have practical applications not only for automatic test equipment (ATE) but also for SoC devices with built-in self-test circuits. The following expression is a March 17N diagnostic algorithm in accordance with the embodiment of the present invention.

[symbol]

(w0) [symbol] (r0,w1,r1) [symbol] (r1,w0,r0) [symbol] (r0,w1) [symbol] (r1,w0

wherein the symbol [symbol] indicates address increment, the symbol [symbol] indicates address decrement, the characters r and w in these brackets respectively represent read and write instructions, and the numbers 0 and 1 are the data that the read or write instruction operates. These read and write instructions are sequentially applied to each memory address, and the read and write operations designated in these brackets are performed in accordance with the direction of the symbols before brackets.

The present invention employs March signatures to highlight results of the finishing of all the instructions in this algorithm, wherein number 0 stands for a correct behavior and number 1 stands for an incorrect behavior. Table 1 shows certain March signatures for the March 17N algorithm including signatures of three fault models, namely SAF0, SAF1 and RDF0. During the interval of the memory defect diagnosis, the practical operation results are compared with the signatures in Table 1, and fault models predefined in Table 1 should be detected.

TABLE 1
March signatures

| Fault model | March signature |
|---|---|
| SAF0 | 00011000010000011 |
| SAF1 | 01000011000111000 |
| RDF0 | 00000001000011000 |

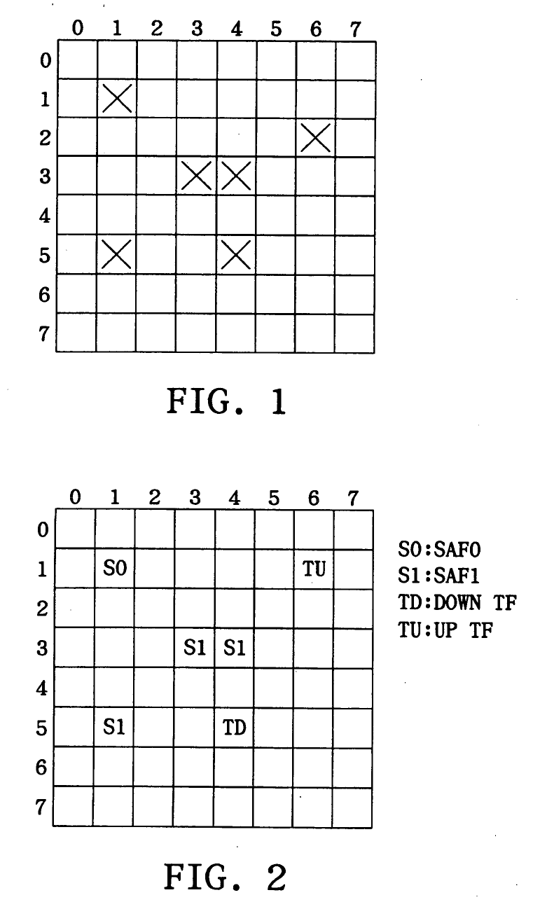

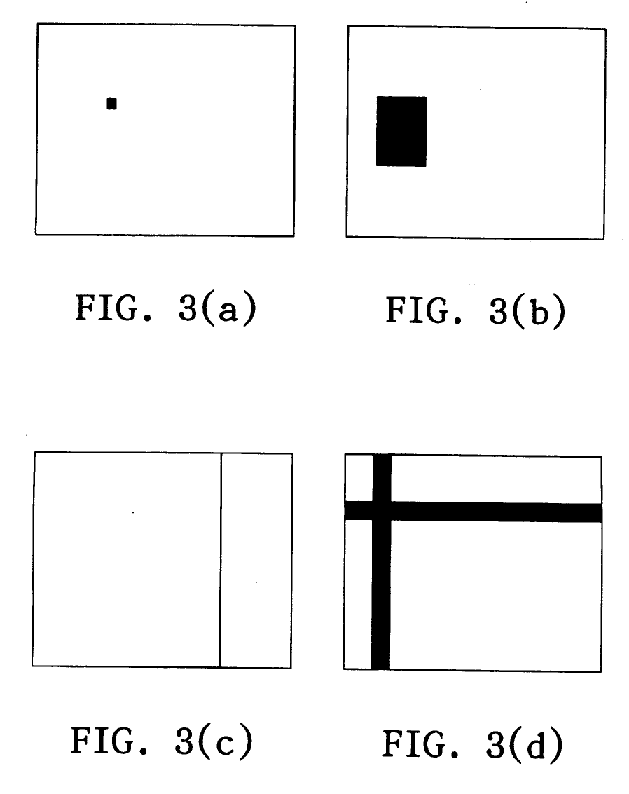

When a memory is tested by the algorithm, a failure bitmap can be constructed automatically as a testing result by the ATE, as shown in FIG. 1. The places marked with “X” represent defective memory cells, and the failure bitmap can be changed into a fault bitmap as shown in FIG. 2 through the diagnosis of an error analyzer, wherein the abbreviations S0, S1, TD and TU respectively represent the fault models SAF0, SAF1, DOWN TF and UP TF.

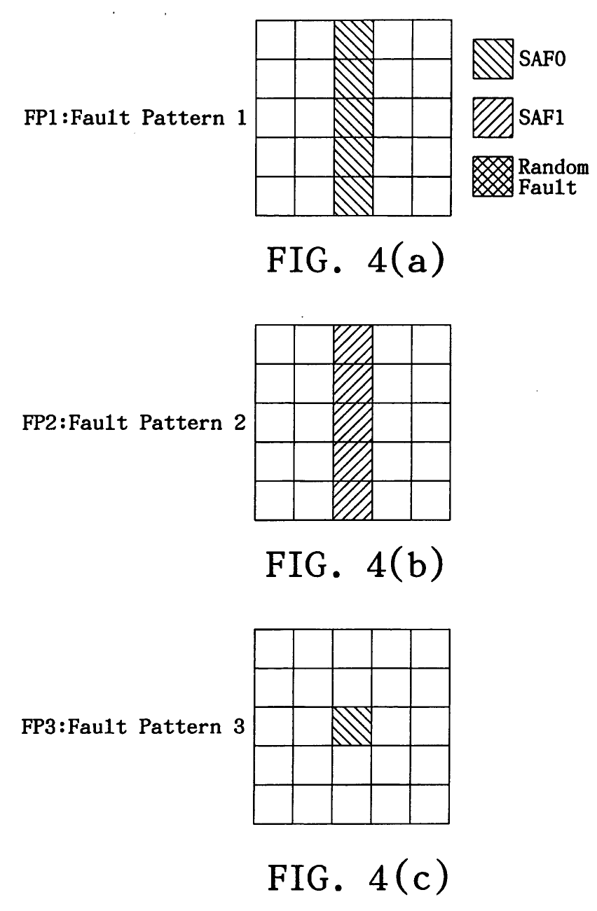

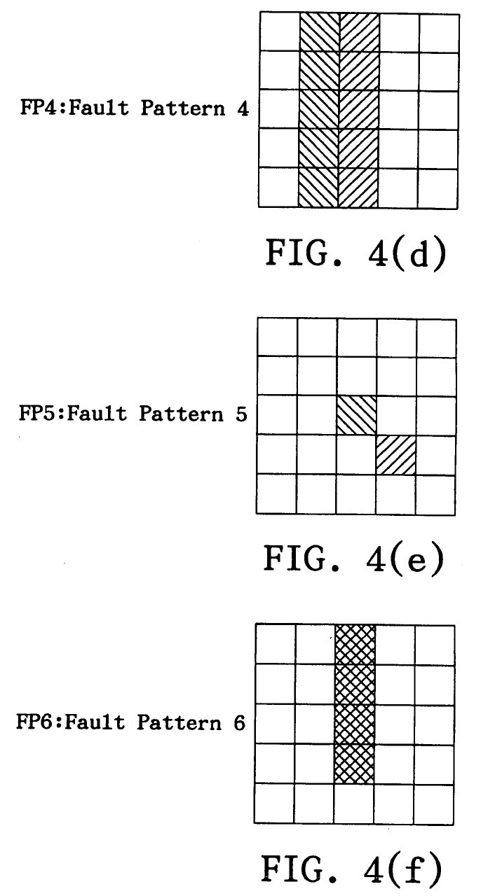

The memory failure bitmaps in FIG. 1 can be further rearranged and classified as various failure patterns. For example, FIG. 3(a) shows the failure pattern having a single failure cell; FIG. 3(b) shows the failure pattern having a cluster of failure cells; FIG. 3(c) shows the failure pattern having a column of failure cells; and FIG. 4(c) shows the failure pattern having a cross region of failure cells. Through failure analyses or process simulations, possible defects corresponding to one of the failure patterns can be found.

However, the possible defects diagnosed by the failure patterns are not sufficient and may easily cover the real root causes of the failures due to a low resolution, that is, different fault behaviors are referred to the same failure pattern. For example, the GND of a memory shorts to the BL (bit line) of the one, and we can obtain a failure pattern having a column of failure cells as shown in FIG. 3(c). Unfortunately, if the GND of a memory shorts to the BLb (\overline{bit-line}) of the one, we also can obtain the same failure pattern as FIG. 3(c). Failure memory cells, where exist, are discriminated from others through aforementioned procedures, but real root causes of these failures are quite unclear.

In order to find out the real root causes of the failure memory cells effectively, the present invention have the combination of failure patterns and failure bitmaps especially on their characteristics to provide fault patterns so as to further confirm which possible defect the failure memory cell has. FIGS. 4(a)-4(f) are schematic diagrams of fault patterns displaying a memory array consisting of 5×5 memory cells in accordance with the present invention. The six fault patterns respectively represent specific possible defects that are the result of the execution of a faulty circuit simulation after engineers estimate the possible occurrence of the faults. This present invention establishes a defect dictionary by collecting the fault patterns and the corresponding possible defects into a dictionary. The root causes of failures are further clarified through mapping the fault bitmaps of a memory to the possible defects of the dictionary. Table 2 is a defect dictionary of the six fault patterns FP1-FP6 in accordance with FIGS. 4(a)-4(f).

TABLE 2
Defect dictionary

| Fault pattern | Probable defects |
|---|---|
| FP1 | 1. VDD shorts to BLb |
| | 2. GND shorts to BL |
| FP2 | 1. VDD shorts to BL |
| | 2. GND shorts to BLb |
| FP3 | 1. VDD shorts to Db |
| | 2. GND shorts to D |
| | 3. Open between Db and M6 |
| FP4 | BLi shorts to BLbi + 1 |
| FP5 | 1. Di shorts to Dbi + 1 |
| | 2. Dbi shorts to Di + 1 |
| FP6 | BL opens |

Note:
1. Suffix i denotes the index of a column or low.
2. D denotes cell-data.
3. Db denotes complementary cell-data.
4. M6 denotes a pass transistor.

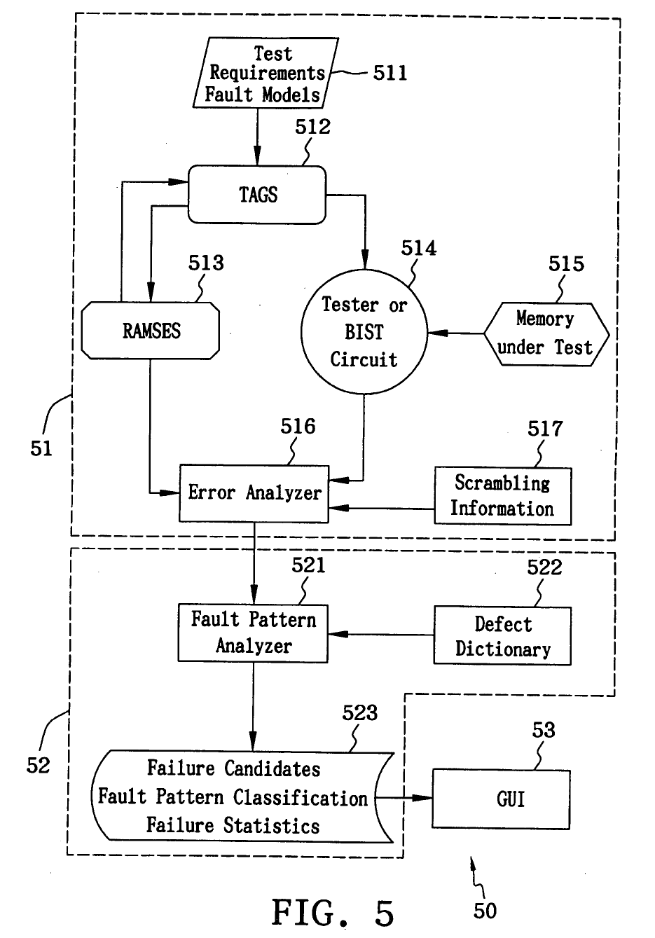

FIG. 5 is a framework and flow diagram of a defect diagnosis system for memories in accordance with the present invention. This memory defect diagnosis system 50 comprises two primary modules, namely MECA 51 (memory error catch and analysis) and MDD 52 (memory defect diagnosis). The MECA 51 proposed before by the major inventor of the present invention is a memory testing system, and is applicable to automatic test equipment, a tester or a SoC device with BIST (built-in self-test) circuit 514. Before a MUT (memory under test) 515 starts to be tested, test requirements and fault models 511 is required to be established first. After that, the fault models are associated with a TAGS (test algorithm generator) 512, and the tester or BIST circuit 514 executes a series of detecting operations from a test or a diagnostic algorithm (e.g., a March 17N algorithm). The present invention can additionally use a RAMSES (random access memory simulator for error screening) 513 to simulate the behavior of each fault model, namely the March signature, and the memory cells where fault models possibly exist are detected through iteration operations between the TAGS 512 and RAMSES 513. The RAMSES 513 can enhance the fault coverage and the diagnostic resolution of the TAGS 512.

The data log of the tester or BIST circuit 514 and the March syndrome of the RAMSES 513 are together input to an error analyzer 516, then the error analyzer 516 can analyze which fault model the failure memory cell is referred to and constructs a fault bitmap. Usually, continuous logic addresses are adapted to the diagnosis system, so that scrambling information 517 is required to transfer the logic addresses to physical addresses in accordance with the failure bitmaps.

A fault pattern analyzer 521 analyzes and diagnoses these fault bitmaps and other corresponding data. The defect dictionary 522 can designate or highlight defect/failure candidates (For example, VDD shorts to BLb.), failure/fault pattern classification and failure statistics 523. Circuit designers can modify the corresponding circuit layout or change the corresponding manufacturing process to improve the yield of the SoC devices by employing the fault pattern analyzer 521.

It is noteworthy that the embodiment of the present invention is not limited to integrate the MDD 52 with MECA 51 to work together. If a module or a sub-system can input the failure bitmaps and test results to an MDD for analysis and diagnosis as the MDD 52 does, it is still in the scope of the present invention.

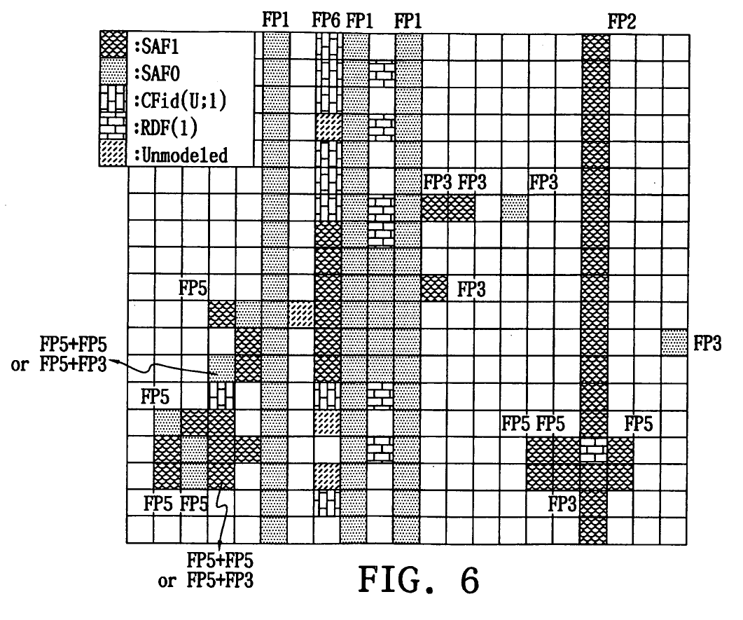

In order to have a friendly display for any user to read the result of the defect analysis and diagnosis, the present invention further provides a GUI 53. FIG. 6 is a schematic diagram of a GUI page for browsing a diagnostic result in accordance with the present invention. The GUI 53 directly displays the fault models and fault patterns on the physical addresses of the memory cells, thus users can easily know which fault pattern exists in which memory cell. That is, the readability of the analytic and diagnostic results is abruptly increased.

The above-described embodiments of the present invention are intended to be illustrative only. Numerous alternative embodiments may be devised by persons skilled in the art without departing from the scope of the following claims.

What is claimed is:

1. A method of fault pattern oriented defect diagnosis for memories, comprising the steps of:
testing a memory to obtain a fault bitmap;
analyzing the fault bitmap by means of a defect dictionary including a plurality of fault patterns; and
showing causes of defects occurring in the memory.

2. The method of fault pattern oriented defect diagnosis for memories of claim 1, further comprising the steps of:
preselecting a plurality of expected possible defects; and
executing a faulty circuit simulation for each of the defects of the memory to find out the corresponding fault pattern thereof.

3. The method of fault pattern oriented defect diagnosis for memories of claim 1, further comprising a step of showing fault pattern classification and failure statistics of the memory.

4. The method of fault pattern oriented defect diagnosis for memories of claim 1, further comprising a step of providing a GUI for a user to browse the fault patterns and diagnostic results of the memory.

5. The method of fault pattern oriented defect diagnosis for memories of claim 1, further comprising a step of associating a fault model with its fault bitmap to define each of the fault patterns.

6. A method of fault pattern oriented defect diagnosis for memories, comprising the steps of:
preselecting an expected possible defect of a memory;
executing a faulty circuit simulation for the defect to find out a corresponding fault pattern;
grouping a plurality of the fault patterns to build up a defect dictionary; and
analyzing causes of the defects occurring in the memory by means of the defect dictionary.

7. The method of fault pattern oriented defect diagnosis for memories of claim 6, further comprising a step of showing fault pattern classification and failure statistics of the memory.

8. The method of fault pattern oriented defect diagnosis for memories of claim 6, further comprising a step of providing a GUI for a user to browse the fault patterns and diagnostic results of the memory.

9. The method of fault pattern oriented defect diagnosis for memories of claim 6, further comprising a step of associating a fault model with its fault bitmap to define each of the fault patterns.

10. A system of fault pattern oriented defect diagnosis for memories, comprising:
a defect dictionary including a plurality of fault patterns, wherein each of the fault patterns is represented by a fault bitmap resulted from a defect; and
a fault pattern analyzer for analyzing causes of the defects occurring in a memory according to the defect dictionary.

11. The system of fault pattern oriented defect diagnosis for memories of claim 10, further comprising an error analyzer capable of generating the fault bitmap of the memory, which is analyzed by the fault pattern analyzer.

12. The system of fault pattern oriented defect diagnosis for memories of claim 10, further comprising a GUI for a user to browse the fault patterns and diagnostic results of the memory.

13. The system of fault pattern oriented defect diagnosis for memories of claim 10, wherein the fault pattern analyzer includes an apparatus showing fault pattern classification and failure statistics.
